(19) United States
(12) Patent Application Publication
(10) Pub. No.: US 2002/0033518 A1
(43) Pub. Date: Mar. 21, 2002

(54) INTEGRATED CIRCUIT RESISTOR STRUCTURE

(76) Inventor: JEAN-NOEL DIVOUX, LA CHAUX-DE-FONDS (CH)

Correspondence Address: GRIFFIN BUTLER WHISENHUNT & SZIPL LLP, SUITE PH-1, 2300 NINTH STREET SOUTH, ARLINGTON, VA, 222042396

(21) Appl. No.: 09/084,128

(22) Filed: May 26, 1998

(30) Foreign Application Priority Data
May 29, 1997 (CH) 1265/97

(51) Int. Cl. H01L 29/00

(52) U.S. Cl. 257/528

(57) ABSTRACT

The present invention concerns an integrated circuit resistor structure (10) comprising a well (1) formed in a substrate (2), and having a first type of conductivity, and a diffusion zone (3) formed in said well (1), and having a second type of conductivity different from said first type of conductivity. Said well (1) is provided with first and second contact terminals (5B, 7B), so as to form a first resistor (Rwell) in said well (1), and said diffusion zone (3) is provided with third and fourth contact terminals (5A, 7A) so as to form a second resistor (Rdiff) in said diffusion zone (3). This structure further comprises means (11) for connecting external terminals (M, N) with said first, second, third and fourth contact terminals, so as to form a selected combination of the first and second resistors among a plurality of combinations.

The present invention concerns the field of integrated circuit resistor structures.

There exist different types of resistor structures formed in integrated circuits, according to the prior art. In particular, an integrated circuit resistor structure is conventionally made comprising a diffusion zone of a first type of conductivity, formed in a well of a second type of conductivity different from the first type of conductivity. In an integrated circuit substrate, an insulating zone intended to insulate the diffusion zone from the other components connected on the same substrate, is commonly called a <<well>>.

Japanese application No 01268049 discloses an integrated circuit device including a resistor structure of the aforementioned type, this structure being shown schematically in FIG. 1 of the present description. A well 1 is formed in a substrate 2, by implantation of impurities of a first type of conductivity in said substrate. A resistor is then formed by a diffusion zone 3 in well 1 by implantation of impurities of a second type of conductivity in well 1. The resistor structure includes two contact terminals 5A and 7A arranged so as to form a first resistor Rdiff in diffusion zone 3, and intended to be connected to another component, via contact terminals arranged outside said resistor structure. The resistor structure further includes two additional contact terminals 5B and 7B arranged so as to form a second resistor Rwell in well 1.

The aforementioned Japanese application shows that the connection between contact terminals 5A, 5B, 7A and 7B is arranged so that resistor Rwell is connected in parallel with resistor Rdiff.

Such structures of the type shown in FIG. 1 have the drawback of occupying a significant surface area across the substrate, in order to form a resistor of high resistance characteristics. Moreover, the resistivity and temperature dependence characteristics of said resistor are determined by the nature of the material selected for forming the diffusion zone, which may be particularly disadvantageous for certain applications of such a resistor.

An object of the present invention is to provide an integrated circuit resistor structure capable of providing variable resistivity and temperature dependence characteristics.

Another object of the present invention is to provide such a structure which answers conventional industrial criteria of packing density, complexity and cost.

These objects, in addition to others, are achieved by the integrated circuit resistor structure according to claim 1.

One advantage of the resistor structure according to the present invention is obtaining a greater resistance than the single resistance of the diffusion zone, while occupying the same surface area.

Another advantage of the resistor structure according to the present invention is being able to obtain different resistor configurations from the same resistor structure, these configurations each having specific resistivity and temperature dependence characteristics, able to be adapted to different use requirements.

These objects, features and advantages of the present invention, in addition to others, will appear more clearly upon reading the detailed description of a preferred embodiment of the invention, given solely by way of example, with reference to the annexed drawings, in which:

FIG. 1 already cited shows an integrated circuit resistor structure according to the prior art;

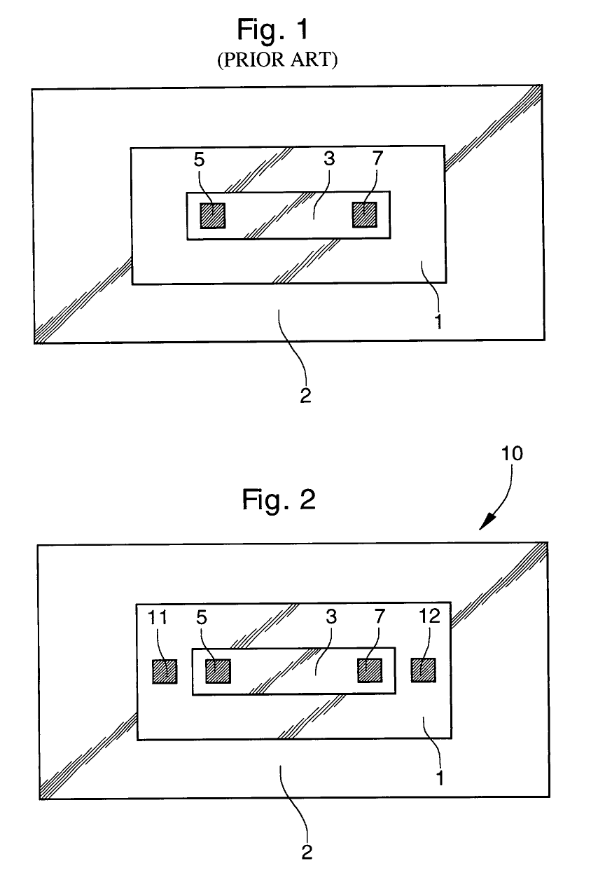

FIG. 2 shows an integrated circuit resistor structure according to the present invention;

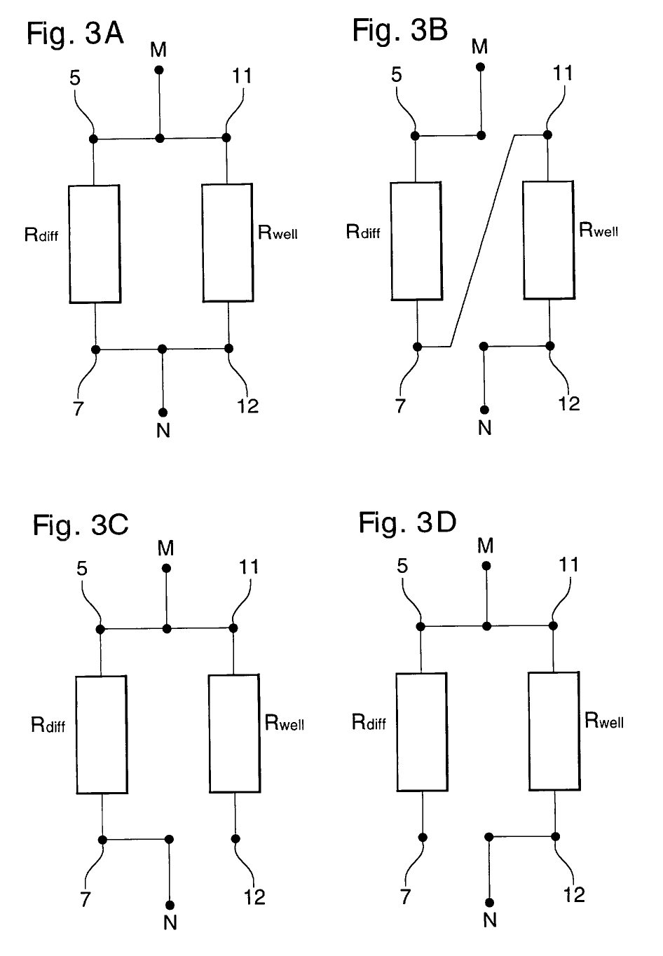

FIGS. 3A to 3D show four equivalent electric diagrams corresponding to different combinations of the structure of FIG. 2, respectively;

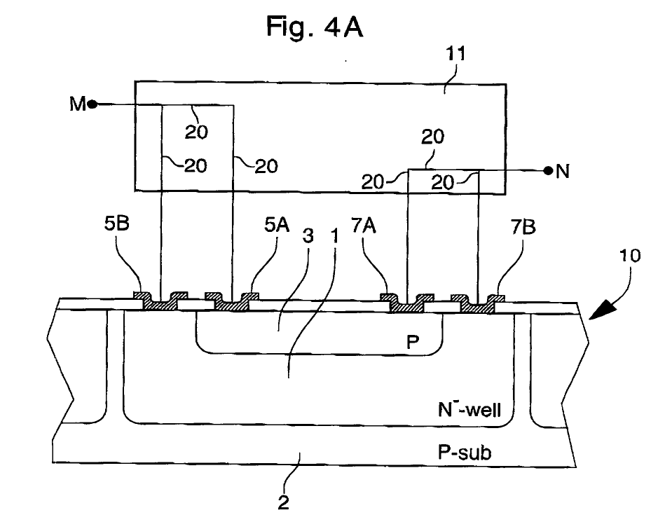

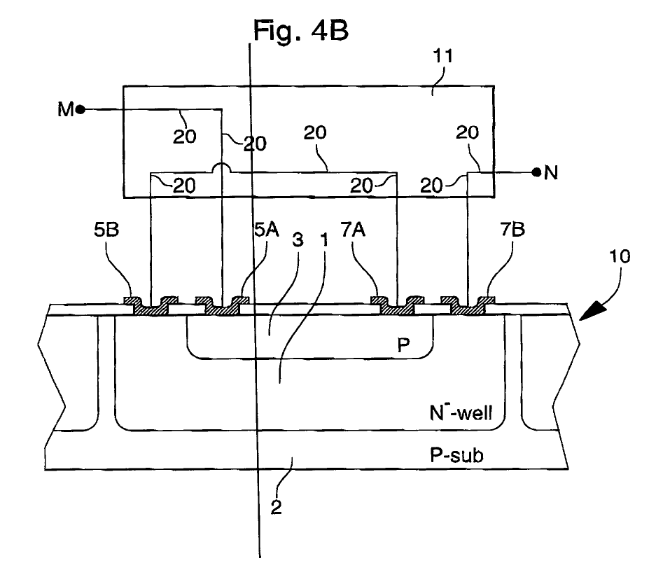

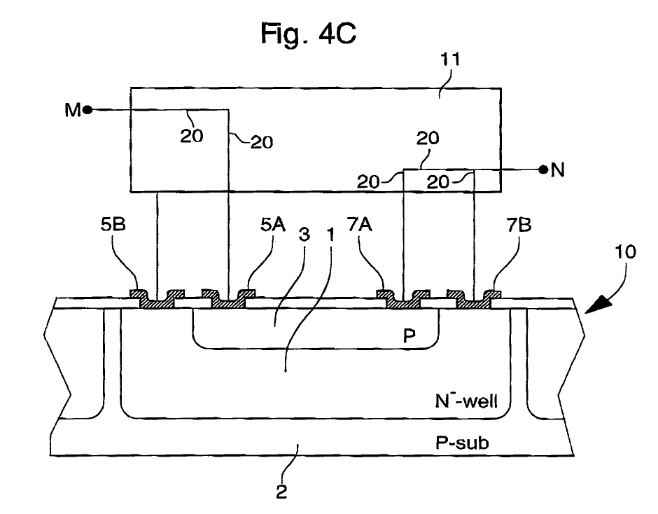

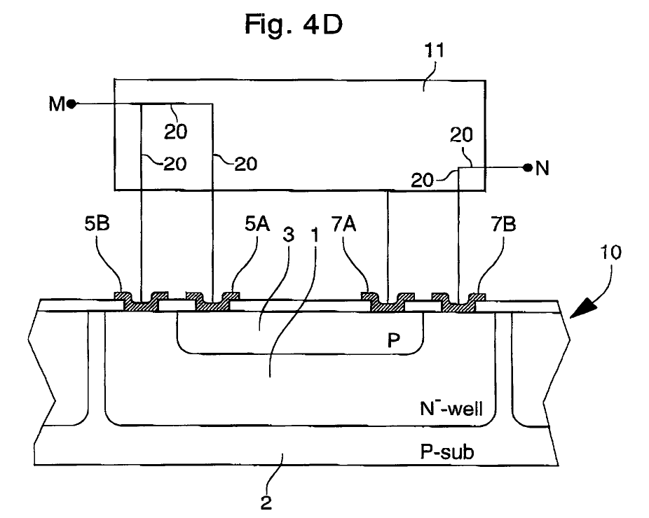

FIGS. 4A to 4D show a first embodiment of the connection means of the structure of FIG. 2, according to the four equivalent electric diagrams of FIGS. 3A to 3D, respectively;

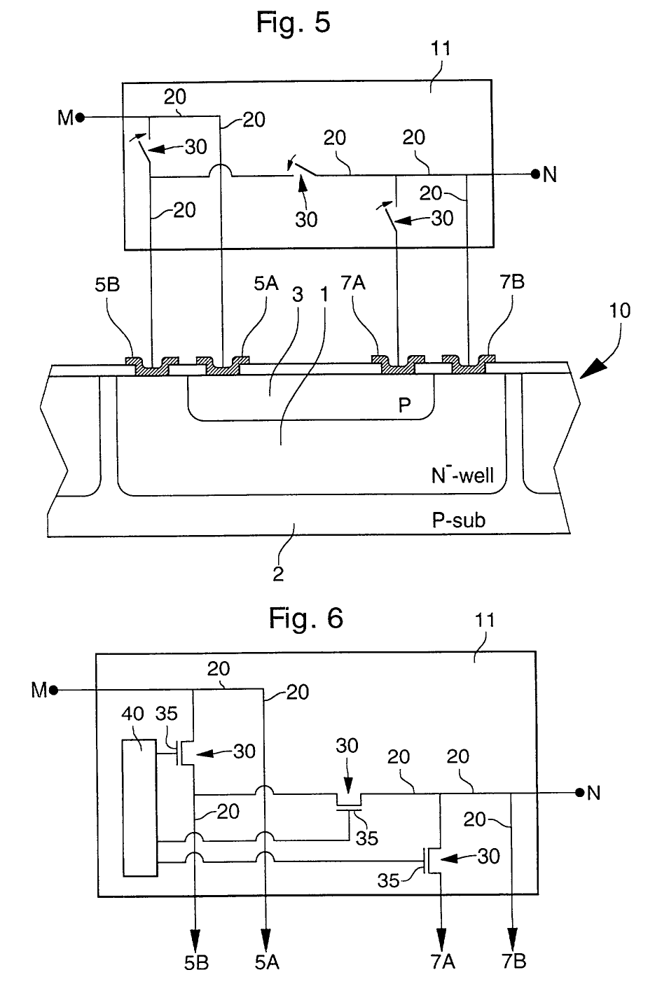

FIG. 5 shows a second embodiment of the connection means of the structure of FIG. 2; and

FIG. 6 shows an embodiment of the switches relative to the connection means of FIG. 5.

FIG. 2 shows an integrated circuit resistor structure 10 according to the present invention.

It will be noted that structure 10 is close to the conventional structure shown in FIG. 1. Thus, the components of FIG. 2 designated by the same numerals as the components of FIG. 1 are the same.

Structure 10 includes a well 1 having a first type of conductivity, this well being provided in a substrate 2, and a diffusion zone 3 having a second type of conductivity, this zone being provided in well 1.

Structure 10 further includes a first pair of contact terminals 5A and 7A provided at the surface of diffusion zone 3, these terminals being arranged so as to form a first resistor Rdiff in diffusion zone 3, i.e. the path for electric charges between terminal 5A and terminal 7A along a path included in diffusion zone 3, and a second pair of contact terminals 5B and 7B, provided at the surface of well 1, so as to form a second resistor Rwell in well 1, i.e. the path for electric charges between terminal 5A and terminal 5B along a path included in well 1.

Structure 10 is further connected to another component, via external contact terminals M and N arranged so as to form the connection of this component to resistors Rwell and Rdiff. This component can be made in a different integrated circuit substrate from said substrate 2, or in a zone of said substrate 2 electrically insulated from well 1.

Structure 10 is also fitted with means 11 for connecting contact terminals 5A, 7B, 5B and 7B to each other, these connection means being arranged so as to form a selected combination of resistors Rwell and Rdiff.

Different connection configurations may be made in structure 10. FIGS. 3A to 3D show four equivalent electric diagrams corresponding to four different selected combinations of resistors Rwell and Rdiff, given solely by way of example.

It is to be noted, in FIGS. 3A to 3D, that numerals 5A, 7A, 5B and 7B designate similar contact terminals to those designated by the same numerals in FIG. 2.

FIG. 3A shows the electric diagram equivalent to the fist combination wherein resistors Rdiff and Rwell are connected in parallel between terminals M and N. For this purpose, the aforementioned connection means are arranged so that they connect, in this configuration, terminal M to terminals 5A and 5B, and terminal N to terminals 7A and 7B.

FIG. 3B shows the electric diagram equivalent to the second combination wherein resistors Rdiff and Rwell are connected in series between terminals M and N. For this purpose, the aforementioned connection means are arranged so that they connect, in this configuration, terminal M to terminal 5A, terminal N to terminal 7B, and terminal 7A to terminal 5B.

FIG. 3C shows the electric diagram equivalent to the third combination wherein only resistor Rdiff is connected between terminals M and N. This configuration is close to that described hereinbefore, with reference to FIG. 1, showing an integrated circuit resistor structure according to the prior art. For this purpose, the aforementioned connection means are arranged so that they connect, in this configuration, terminal M to terminal 5A, and terminal N to terminal 7A. Preferably one of terminals 5B and 7B, for example terminal 7B, is connected to one of terminals 5A and 7A, for example terminal 7A, so as to bias well 1, and to oppositely bias the junction between well 1 and diffusion zone 3, as is shown by FIG. 3C. As a variant, terminals 5B and 7B can be not connected, the voltage of well 1 then being floating.

FIG. 3D shows the electric diagram equivalent to the fourth combination wherein only resistor Rwell is connected between terminals M and N. For this purpose, the aforementioned connection means are arranged so that they connect, in this configuration, terminal M to terminal 5B, and terminal N to terminal 7B. Preferably one of terminals 5B and 7B, for example terminal 5B, is connected to one of terminals 5A and 7A, for example terminal 5A, so as to bias well 1, and to oppositely bias the junction between well 1 and diffusion zone 3, as is shown by FIG. 3D. As a variant, terminals 5B and 7B can be not connected, the voltage of well 1 then being floating.

FIG. 4A to 4D show a first embodiment of connection means 11 of structure 10 of FIG. 2, according to the four electric diagrams of FIGS. 3A to 3D respectively.

Referring to FIG. 4A, connection means 11 are formed by six conductive strips 20 arranged for example in substrate 2. Strips 20 are connected to form the electric diagram of FIG. 3A.

FIG. 4B is a similar figure to FIG. 4A, wherein connection means 11 comprise seven conductive strips 20. These strips are arranged to form the electric diagram of FIG. 3B.

FIGS. 4C and 4D are similar figures to FIG. 4A, wherein connection means 11 comprise five conductive strips 20. These strips are arranged to form the electric diagrams of FIGS. 3C and 3D, respectively.

It is noted in that numerals 20 in FIGS. 3A to 3D designate conductive strips 20 in the equivalent electric diagram of FIGS. 3A to 3D, respectively.

FIG. 5 show a second embodiment of connection means 11 of the structure of FIG. 2.

Referring to FIG. 5, connection means 11 are formed by an arrangement of conductive strips 20 and switches 30. In the example of FIG. 5, three switches 30 are connected with conductive strips 20 between contact terminals 5A, 5B, 7A and 7B and external terminals M and N.

Each of switches 30 can be switched in a position <<ON >> or <<OFF>>, in response to a control signal which can be provided by control means. FIG. 6 shows an embodiment of switches 30 which comprise conventional MOS-FET transistors 35. These transistors are controlled by a conventional microprocessor 40 which forms said control means.

Thus, connection means 11 can be configured upon demand in any of the four electric diagrams of FIGS. 3A to 3D. In other words, switches 30 allow the selection of said selected combination.

Therefore, connection means 11 can be sequentially configured according to the four diagrams of FIGS. 3A to 3D. For instance, during a two-phase period, connection means 11 can be in the configuration of the electric diagram of FIG. 3A during the first phase, and in the configuration of the electric diagram of FIG. 3B during the second phase.

An advantage of the resistor structure according to the present invention is being able to obtain different resistor configurations from the same resistor structure, these configurations each having specific resistivity and temperature dependence characteristics, able to be adapted to different use requirements.

Specific electric and heat properties are associated with each of these configurations.

Solely by way of illustration, the Applicant of the present invention has measured some characteristic values of configurations A to D described in relation to FIGS. 3A to 3D, respectively. These values are the total resistance measured at 25° C. over one of the aforementioned configurations, this resistance being designated Rₜₒₜ, the sheet resistance associated with resistance Rₜₒₜ, this resistance being designated R/□ being known to those skilled in the art, and the temperature coefficient designated ΔR/Ro, this coefficient being equal to the total resistance variation for a temperature variation of 1° C. Table I hereinafter shows these values for configurations A to D formed in a structure 10 which has the following dimensions. Well 1 of this structure has a depth equal to 2.0 μm, a length equal to 1.8 mn and a width equal to 8 μm, and diffusion zone 3 of this structure has a depth equal to 0.44 μm, a length equal to 1.8 mn and a width equal to 2 μm.

TABLE I

| Configuration | Rtot (KΩ) | R/□ (Ω/□) | ΔR/Ro (%/° C.) |
|---|---|---|---|
| A | 40.5 | 45.8 | 1.4 |
| B | 560.3 | 2376.9 | 4.4 |
| C | 44.1 | 49.9 | 1.2 |
| D | 516.5 | 2327.0 | 4.7 |

It is to be noted that the different configurations A to D of the same structure 10 allow total resistances Rtot to be achieved comprised between 40.5 and 560.3 KΩ, as well as temperature coefficients ΔR/Ro varying between 1.2 and 4.7%/° C.

Moreover, those skilled in the art will note that configuration B wherein well and diffusion zones are connected in series has a sheet resistance of approximately 2380 KΩ/□n. Thus, structure 10 is particularly advantageous in that it allows a resistor configuration to be achieved having a sheet resistance two times greater than that of a well having the same geometry, and not including a diffusion zone (typically 1530 KΩ/□).

It is noted that the structure according to the present invention can be made by a manufacturing method including known manufacturing steps. Preferably, connection means 11 are formed monolithically from substrate 2, i.e. fabricated in a single chip. for instance, conductive strips 20 can be formed by depositing a metal layer by any conventional technique such as Chemical Vapor Deposition technique.

As an example, and referring to FIGS. 4A to 4D, a well 1 is formed in a substrate 2 by implanting impurities of a first type of conductivity, masking the other zones of the substrate. Likewise, a diffusion zone 3 is formed by implanting impurities of a second type of conductivity. Contact terminals 5A, 7A, 5B and 7B are then formed as well as connection means 11 between said terminals, via conventional steps consisting of: depositing a metal layer over substrate 2, in particular over well 1 and diffusion zone 3; depositing a layer of photoresist over said metal layer; insulating and developing the photoresist layer; etching the exposed zones of the metal layer; and eliminating the remaining photoresist.

Those skilled in the art will note that said connection means, as well as said contact terminals, may advantageously be formed when the different connection structures of the circuits formed in said substrate are made.

An advantage of such a manufacturing method is including already known manufacturing steps, which make said structure inexpensive and easy to make.

It goes without saying for those skilled in the art that the detailed description hereinbefore can undergo various modifications without departing from the scope of the present invention.

What is claimed is:

1. An integrated circuit resistor structure comprising:
a well formed in a substrate, and having a first type of conductivity, said well being provided with first and second contact terminals, so as to form a first resistor in said well;
a diffusion zone formed in said well, and having a second type of conductivity different from said first type of conductivity, said diffusion zone being provided with third and fourth contact terminals so as to form a second resistor in said diffusion zone; and
means for connecting external terminals with said first, second, third and fourth contact terminals, so as to form a selected combination of said first and second resistor among a plurality of combinations.

2. A structure according to claim 1, wherein said connection means are formed by a plurality of conductive strips connected with said first, second, third and fourth contact terminals, so as to form the electric diagram corresponding to said selected combination.

3. A structure according to claim 1, wherein said connection means are formed by a plurality of conductive strips and a plurality of switches connected with said first, second, third and fourth contact terminals, said switches being switched in a position ON or OFF so as to allow the selection of any of said combinations.

4. A structure according to claim 1, wherein said selected combination is such that said first and second resistors are connected in parallel.

5. A structure according to claim 1, wherein said selected combination is such that said first and second resistors are connected in series.

6. A structure according to claim 1, wherein said selected combination is such that only said first resistor is connected.

7. A structure according to claim 1, wherein said selected combination is such that only said second resistor is connected.

8. A structure according to claim 3, wherein said switches are formed by MOS-FET transistors.

9. A structure according to claim 8, wherein said transistors are controlled by control means.

10. A structure according to claim 9, wherein said control means include a microprocessor.

11. A structure according to claim 1, wherein said connection means are formed monolithically in said substrate.
